(19) United States
(12) Patent Application Publication
(10) Pub. No.: US 2016/0052789 A1
(43) Pub. Date: Feb. 25, 2016

(54) TECHNIQUES FOR FABRICATING DIAMOND NANOSTRUCTURES

(71) Applicant: THE TRUSTEES OF COLUMBIA UNIVERSITY IN THE CITY OF NEW YORK, New York, NY (US)

(72) Inventors: Ophir Gaathon, New York, NY (US); Dirk R. Englund, New York, NY (US); Jonathan Hodges, Princeton, NJ (US); Luozhou Li, Ridge, NY (US); Matthew Trushem, Cambridge, MA (US)

(73) Assignee: THE TRUSTEES OF COLUMBIA UNIVERSITY IN THE CITY OF NEW YORK, New York, NY (US)

(21) Appl. No.: 14/841,922

(22) Filed: Sep. 1, 2015

Related U.S. Application Data
(63) Continuation of application No. PCT/US2014/020565, filed on Mar. 5, 2014.
(60) Provisional application No. 61/773,712, filed on Mar. 6, 2013.
(60) Provisional application No. 61/794,510, filed on Mar. 15, 2013.

(51) Int. Cl. C01B 31/06; H01J 37/32; C09K 11/65

(52) U.S. Cl. CPC C01B 31/065; C09K 11/65; H01J 37/32651; H01J 37/32788; H01J 2237/3341; H01J 2237/339

(57) ABSTRACT

Techniques for fabricating diamond nanostructures including application of a self-assembled hard mask to a surface of a diamond substrate to define a pattern of masked regions having a predetermined diameter surrounded by an exposed portion. The exposed portion can be vertically etched to a predetermined depth using inductively coupled plasma to form a plurality of nanoposts corresponding to the masked regions. The nanoposts can be harvested to obtain a nanostructure with a diameter corresponding to the predetermined diameter and a length corresponding to the predetermined depth.

### CROSS-REFERENCE TO RELATED APPLICATIONS

This application is a continuation of International Patent Application No. PCT/US2014/020565, filed Mar. 5, 2014, which claims priority from U.S. Provisional Application Serial Nos. 61/773,712, filed on Mar. 6, 2013, and 61/794,510, filed on Mar. 15, 2013, which are incorporated herein by reference in their entireties.

### BACKGROUND

The disclosed subject matter provides techniques for fabricating diamond nanostructures.

Diamond nanocrystals can be doped with certain color centers with corresponding properties. The negatively charged nitrogen-vacancy (NV) center can be a useful fluorescent probes with field sensing capabilities for a range of applications including neural activity mapping, electric field sensing, room temperature magnetic resonance imaging, nanoscale magnetometry, quantum optics, and biophysics.

Certain conventional magnetometry tools do not achieve nanometer-scale spatial resolution and nT magnetic field resolution in the same device. For example, the sensitivity required for neural sensing can be ˜10 nT and dependent on the distance of the sensor from the neuron surface. The NV center has an electronic spin triplet ground state with up to millisecond-coherence times in high-purity bulk diamond, representing a very long electron spin coherence time for a room-temperature solid-state system. By the application of optical and microwave pulse sequences, particular quantum states of the NV spin triplet can be prepared. Due to their long coherence times, these states can respond to minute external electric or magnetic fields that cause measurable changes in the NV fluorescence. Thus, the NV center can sense magnetic and electric fields at sub-100 nm distances under ambient conditions. In addition to the sensitivity of NV color centers, they can be used for super-resolution imaging.

However, certain available diamond nanocrystals do not have NV centers with long spin coherence times due to low purity and fabrication damage. For certain NV sensing microscopy techniques, high-purity diamond crystals capable of hosting NV centers with long spin coherence times can be required. Accordingly, there remains a need for techniques to fabricate diamond nanostructures in an efficient and cost effective manner.

### SUMMARY

The disclosed subject matter provides techniques for fabricating diamond nanostructures, including diamond nanostructures for use as nanosensors and fluorescent probes, or otherwise for use in life sciences, chemistry, physics, material science and engineering, telecommunications, quantum information processing, or other areas in which diamond nanostructures are desired or beneficial.

In one aspect of the disclosed subject matter, techniques for fabricating diamond nanostructures are provided. An exemplary method can include applying a hard mask to a surface of a diamond substrate to define a pattern of masked regions having a predetermined diameter surrounded by an exposed portion. The exposed portion can be vertically etched to a predetermined depth using inductively coupled plasma to form a plurality of nanoposts corresponding to the masked regions. The nanoposts can be harvested to obtain a nanostructure with a diameter corresponding to the predetermined diameter and a length corresponding to the predetermined depth.

In an exemplary embodiment, the diamond substrate can include a high-purity diamond, low purity diamond, single crystal diamond, or multi-crystal (polycrystalline) diamond. Application of the hard mask can include applying a high-density monolayer of self-assembled dielectric or metallic nanoparticles. Alternatively, application of the hard mask can include heating a thin, evaporated layer of gold on the surface of the diamond substrate to form a plurality of gold droplets corresponding to the masked regions. Alternatively, the surface of the diamond substrate can be patterned by damaging the upper layer of diamond or contaminating the diamond surface with organic or inorganic material. During the etching process, height variations and/or modifications to the surface are enhanced, thereby creating higher aspect ratio structures with a mean diameter that depends of the type and size of the contaminants.

In an exemplary embodiment, the predetermined diameter of the masked regions can be between approximately 25 nm and 225 nm, and the predetermined depth can bet between approximately 50 nm and 500 nm. In one embodiment, the predetermined diameter of the masked regions can be approximately 50 nm and the predetermined depth can be approximately 80 nm. In another embodiment, the predetermined diameter of the masked regions can be approximately 200 nm and the predetermined depth can be approximately 500 nm. As embodied herein, harvesting the nanoposts can include removing the nanoposts from the diamond substrate by mechanical shaving. Additionally or alternatively, harvesting can include sonication.

In another aspect of the disclosed subject matter, nitrogen atoms can be implanted into one or more of the diamond nanostructures fabricated as disclosed herein. The diamond nanostructure can be annealed at approximately 850° C. to mobilize vacancies in the diamond nanostructure crystal and thereby form nitrogen vacancy centers. The surface of the diamond nanostructure can then be oxidized at approximately 475° C. to change the surface termination of the diamond surface and stabilize at least some of the charged nitrogen vacancy centers.

In another aspect of the disclosed subject matter, a system for fabricating diamond nanostructures can include a masking device, an etching device, and a harvesting device adapted for performing the techniques disclosed herein. In an exemplary embodiment, the making device can include one or more of a spin coater, a dip coater, and sputtering equipment adapted to apply a high-density monolayer of self-assembled dielectric or metallic nanoparticles. Alternatively, the masking device can include one or more of a thermal evaporator, an e-beam evaporator, and sputtering equipment adapted to apply the hard mask by heating a thin, evaporated layer of gold on the surface of the diamond substrate to thereby form a plurality of gold droplets, wherein the plurality of gold droplets correspond to the masked regions. Alternatively, the masking device can include one or more of a sputtering device and an e-beam evaporator adapted to deposit a layer of resist to a surface of the diamond substrate and perform electron beam lithography to selectively remove portions of the resist layer corresponding to the exposed portion to thus define the masked regions.

The harvesting device can include a mechanical device adapted to drag a second diamond slab having a surface arranged parallel to a plane of the diamond substrate across the plane at the predetermined depth to cleave the nanoposts from the diamond substrate. Alternatively, the harvesting device can include one or more of a vessel containing a solvent adapted to receive the diamond substrate, an agitator adapted to agitate the solvent, and a sonication horn adapted to agitate the solvent for removing the nanopost from the diamond substrate and thereby obtain the nanostructure.

In certain embodiments, the system can further include an ion implantation device, an annealing device, and/or an oxidation device. The implantation device can include an accelerator configured to emit particles with predetermined energies in a beamline. The annealing device can include split tube furnace with vacuum flanges and a vacuum pump. The oxidation device can include one or more of a hot plate or a split furnace tube.

It is to be understood that both the foregoing general description and the following detailed description are exemplary and are intended to provide further explanation of the disclosed subject matter claimed.

The accompanying drawings, which are incorporated in and constitute part of this specification, are included to illustrate and provide a further understanding of the disclosed subject matter.

### BRIEF DESCRIPTION OF THE DRAWINGS

FIG. 1 is a schematic flow chart illustrating techniques for fabrication of diamond nanostructures in accordance with an exemplary embodiment of the disclosed subject matter.

FIG. 2 shows images of a self-assembled hard mask, diamond nanoposts, and a diamond nanostructure in accordance with an exemplary embodiment of the disclosed subject matter.

FIG. 3 is a schematic diagram of a system for fabrication of diamond nanostructures in accordance with an exemplary embodiment of the disclosed subject matter.

FIG. 4 is a schematic diagram of an imaging system for use in connection with diamond nanostructures fabricated in accordance with the disclosed subject matter.

FIG. 5A-5F is a schematic flow chart illustrating techniques for fabrication of diamond nanostructures in accordance with an exemplary embodiment of the disclosed subject matter.

FIG. 6A-6D shows a scanning electron micrographs of FIG. 6A an AuPd mask, FIG. 6B side view and FIG. 6C top-view of nanocrystals attached to bulk diamond, and FIG. 6D nanocrystals separated from bulk and transferred onto a silicon substrate, in accordance with an exemplary embodiment of the disclosed subject matter.

FIG. 7A-7C shows FIG. 7A a scanning confocal image of CVD nanodiamonds on glass with the fluorescence from a single NV indicated by the red square, FIG. 7B a spectrum of a single NV center in a CVD diamond nanocrystal showing the NV ZPL at 638 nm, and FIG. 7c the second-order autocorrelation function of NV photoluminescence indicating single-emitter behavior with g⁽²⁾(0) less than 0.5 and a curve fit to function 1+Ae^{-|(t/τ)|} with g⁽²⁾(0)=0.247 and τ the excited state lifetime 13.57 ns, in accordance with an exemplary embodiment of the disclosed subject matter.

FIG. 8A-8E shows FIG. 8A a continuous-wave ESR under static magnetic field, FIG. 8B Rabi oscillations, FIG. 8C Ramsey interferometry, FIG. 8D Hahn Echo, and FIG. 8E CPMG-n for exemplary NV centers, in accordance with an exemplary embodiment of the disclosed subject matter.

FIG. 9A-9B shows FIG. 9A a magnetic field and pulse sequence for an AC magnetic field with a frequency of 1/2ΔT=35.7 kHz while its amplitude is varied and FIG. 9B magnetometry results for an AC magnetometry sequence performed on an exemplary NV center, consisting of 106 sequence repetitions per point, with a total measurement time per sequence of 32 μs, in accordance with an exemplary embodiment of the disclosed subject matter.

Throughout the drawings, the same reference numerals and characters, unless otherwise stated, are used to denote like features, elements, components or portions of the illustrated embodiments. Moreover, while the disclosed subject matter will now be described in detail with reference to the FIGS., it is done so in connection with the illustrative embodiments.

### DETAILED DESCRIPTION

As disclosed herein, diamond nanostructures can be fabricated by applying a hard mask defining the diameter of the nanostructures to a diamond substrate. Vertical etching using inductively coupled plasma (“ICP”) or reactive ion etching (“RIE”) can be performed with the hard mask applied so as to create a plurality of nanoposts corresponding to masked regions. After etching, the hard mask can be removed from the diamond substrate and the nanoposts can be “harvested” by sonication and/or mechanical shaving. The resulting diamond nanostructures can be used, for example, as nanosensors or in a variety of other suitable applications that will be apparent to those skilled in the art.

It will be apparent to one of ordinary skill in the art that the techniques disclosed herein can provide diamond nanostructures suitable for use in a variety of applications. Additionally, as described herein, certain exemplary embodiments include the creation of atomic defects, such as NV centers, in diamond nanostructures. One of ordinary skill in the art will appreciate that the existence and type of atomic defects can depend on the application, and thus the techniques for creation of atomic defects disclosed herein need not be performed or modified as desired. Accordingly, the disclosed subject matter is not intended to be limited to the exemplary embodiments disclosed herein.

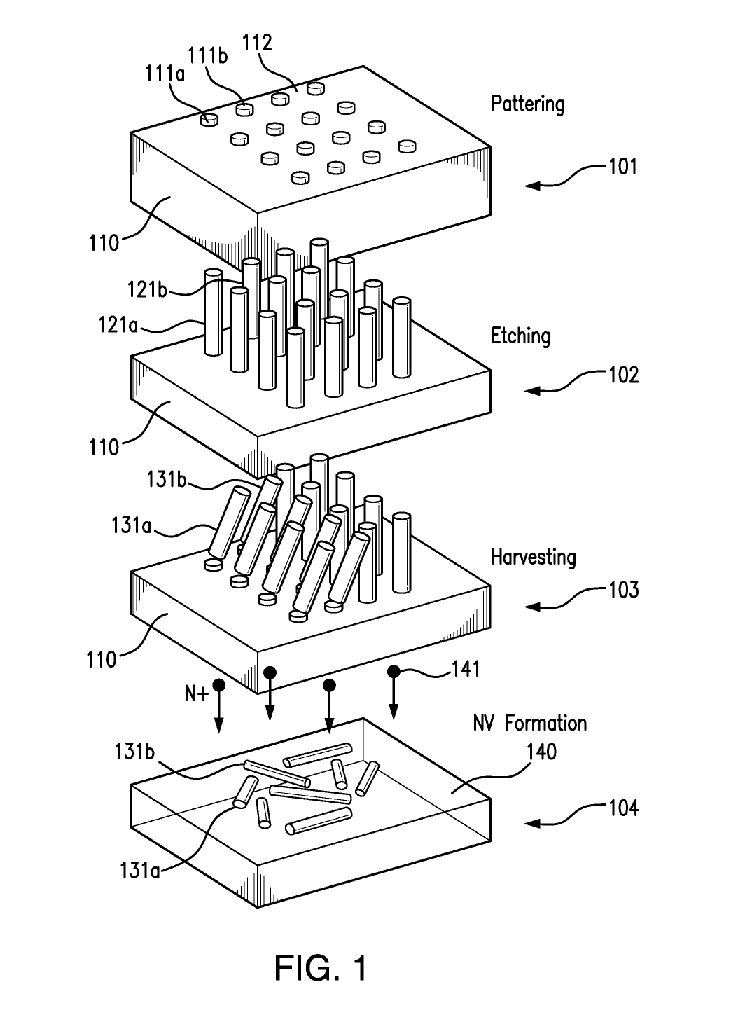

With reference to FIGS. 1-3, and in accordance with an exemplary embodiment of the disclosed subject matter, techniques for fabricating diamond nanostructures (e.g., 131a and 131b [collectively, 131]) can include applying (101) a self-assembled hard mask to a surface of a diamond substrate 110 to define a pattern of masked regions (e.g., 111a and 111b [collectively, 111]) having a predetermined diameter surrounded by an exposed portion 112. In accordance with the disclosed subject matter, the diamond substrate 110 can be any suitable diamond substrate. For example, the substrate can be high-purity diamond (e.g., N<10 ppb), low quality diamond (e.g., N>200 ppb), single crystal diamond, and/or multi-crystal diamond. Moreover, the diamond substrate can be natural or synthetic diamond. In connection with a synthetic diamond substrate, the diamond substrate can be created using high-pressure high-temperature (HPHT) or chemical vapor deposition (CVD) techniques.

As embodied herein, the hard mask can be applied without the use of conventional lithography techniques and without the need to deterministically pattern the masked regions. For purpose of example, and not limitation, such techniques can include applying a hard mask of self-assembled metallic and dielectric nanoparticles or applying a hard mask of gold droplets by heating an evaporated layer of gold on the surface of the diamond substrate. Alternatively, in accordance with the disclosed subject matter, the surface of the diamond substrate can be damaged and/or contaminated with organic or inorganic material such that during the etching process the height variations and/or modifications to the surface are enhanced, thereby creating higher aspect ratio structures corresponding to the size of the contaminants. While described with reference to exemplary embodiments, for purpose of illustration, and not limitation, the disclosed subject matter is not intended to be limited to the exemplary embodiments.

In an exemplary embodiment, the hard mask can be patterned using self-assembled metallic and dielectric nanoparticles. Use of self-assembled masks can provide for enhanced scalability. The hard mask can be applied, for example, over a square centimeter surface area of the diamond substrate 110. As embodied herein, application of the hard mask can include applying a high-density monolayer of dielectric or metallic nanoparticles. For example the hard mask can be applied by sputtering of SiO₂ nanoparticles or thermal evaporation of gold. Alternatively, as an example, Aluminum oxide nano-spheres suspended in a solvent can be applied on the surface by spin coat, drop cast or dip coating. As the solvent evaporates the particles can tend to gather and from a large-scale patterned mask. Particle size can be from a few nanometers to several millimeters. It is recognized that the density of the particles can depend on the specific application and the size of the structures. For example, structures with a diameter of approximately 200 nm can be as close as approximately 20 nm apart.

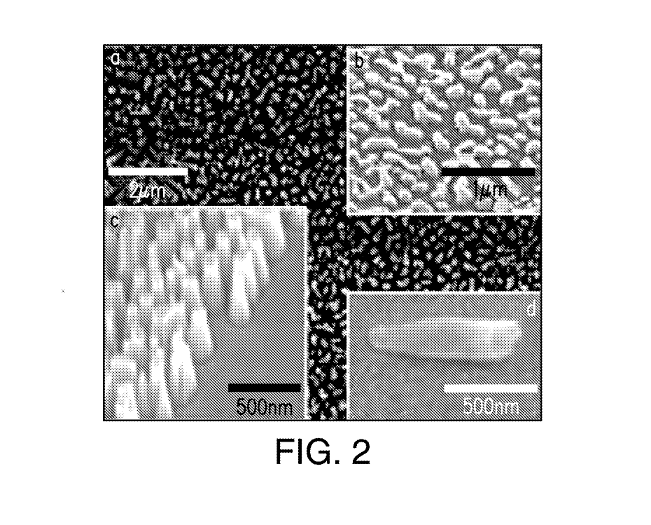

Alternatively, application of the hard mask can include heating a thin, evaporated layer of gold on the surface of the diamond substrate to form a plurality of gold droplets corresponding to the masked regions. The low surface affinity of gold on diamond can cause the formation of gold droplets, as illustrated in FIG. 2a-b. FIG. 2a shows a scanning electron microscope image of gold droplets formed on the diamond substrate. FIG. 2b likewise shows a scanning electron microscope image of gold droplets formed on the diamond substrate at increased magnification. A layer of gold having a thickness of approximately a few nanometers can be evaporated onto the diamond surface and can be heated (e.g., at approximately 250° C. to approximately 350° C.) for several minutes to allow for the gold to form droplets on the surface. The droplets can be, for example, on the order of 10 s of nanometers in diameter.

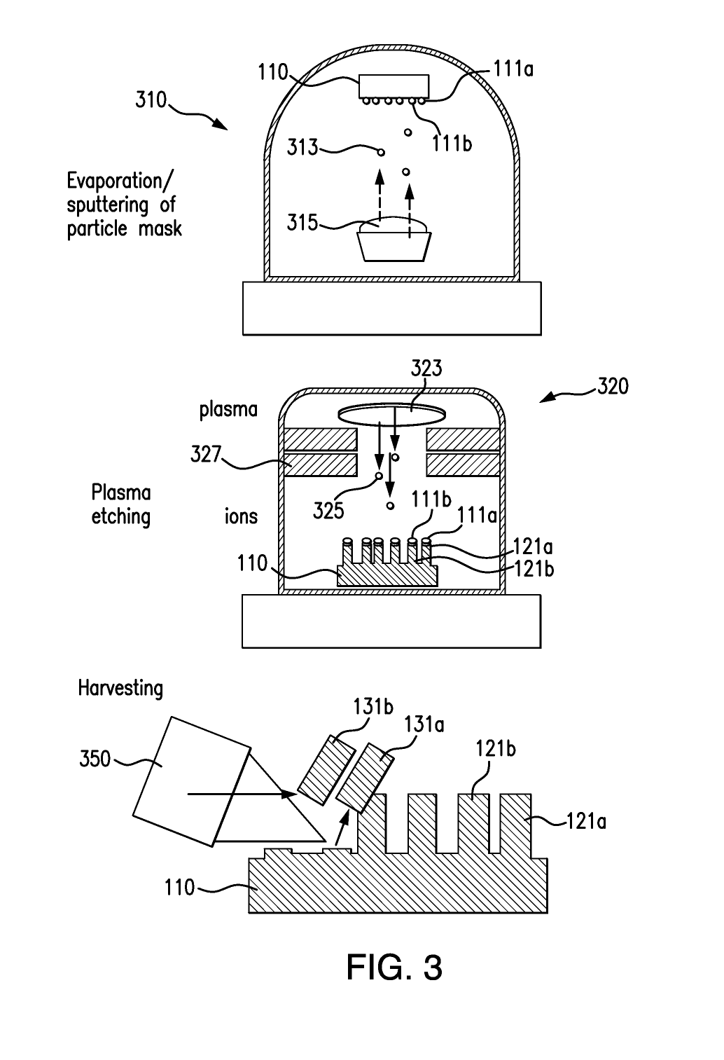

Application of the hard mark from gold droplets can include, for example with reference to FIG. 3, the use of a masking device 310. The masking device can include, for example, a thermal evaporator, e-beam evaporator, and/or sputtering equipment. A layer of gold 315 can be disposed in a sputtering chamber and can be heated with a thermal evaporator or e-beam evaporator to form evaporated gold particles 313. The evaporated gold particles 313 can be applied to the surface of the diamond substrate 110, and the gold particles 313 can form gold droplets 111 due to the affinity of gold to the diamond substrate 110.

Alternatively, in certain embodiments, the hard mask can be applied by other suitable techniques. For example, and not limitation, electron-beam lithography can be used to pattern a hard mask layer. A layer of hard mask resist, which can be formed from a variety of suitable materials, can be deposited on the surface of the diamond substrate 110. A beam of electrons can be emitted across the surface to selectively remove portions of the resist layer to define a pattern of masked regions 111 having a certain diameter surrounded by an exposed portion 112.

Alternatively, the surface can be patterned by damaging the upper layer of the diamond substrate crystal or contaminating the diamond surface with organic or inorganic material. During the etching process these modification/height variations to the surface are enhanced—creating a higher aspect ratio structures with mean diameter that depends of the type and size of the contaminants. For purpose of illustration, and not limitation, the modifications/height variations to the surface of the diamond substrate can, due to diamond's dielectric properties, in essence create a hard mask from the diamond substrate itself during the etching process.

The techniques disclosed herein for application of the hard mask can be employed to create high-selectivity masks for oxygen plasma etching using ICP or RIE, which can thus produce an array of nanoposts (e.g., 121a and 131b [collectively, 121]) across, for example, a square millimeter area of the diamond substrate 110, as illustrated in FIG. 2c. As disclosed herein, nanostructures 131 of several sizes can be produced. For example, the predetermined diameter of the masked regions 111 can be between approximately 25 nm and 225 nm, and the predetermined depth can bet between approximately 50 nm and 500 nm. As embodied herein, self-assembled particles can form structures that are in similar shape to the masking particles or as a composite of several particles per structure. The structures diameter can be from a few nanometers to a diameter on the order of millimeters. In one embodiment, the predetermined diameter of the masked regions 111 can be approximately 50 nm and the predetermined depth can be approximately 80 nm. In another embodiment, the predetermined diameter of the masked regions 111 can be approximately 200 nm and the predetermined depth can be approximately 500 nm.

While the masked regions 111 depicted in FIG. 1 are arranged in an array pattern for purpose of illustration, one of ordinary skill in the art will appreciate, as illustrated by FIG. 2a and FIG. 2b, that the masked regions 111 formed from a self-assembled hard mask need not have a geometric shape (e.g., some mask regions can have an irregular shape) and the arrangement need not be a square lattice. Accordingly, as used herein, the term “approximately” as used in connection with the dimensions of the masked regions 111, the predetermined depth, and/or the dimensions of the nanostructures 131 can include a value one of ordinary skill in the art would consider equivalent to the recited value (i.e., having the same function or result), or a value that can occur, for example, through typical measurement and process procedures.

In accordance with an exemplary embodiment, the exposed portion 112 of the diamond substrate 110 can be vertically etched (102) to a predetermined depth using ICP to form a plurality of nanoposts 121 corresponding to the masked regions 111. As will be appreciated by one of ordinary skill in the art, a suitable ICP recipe can be designed, taking into considerations such as the thickness and composition of masking material and the desired predetermined etch depth. For purpose of illustration, and not limitation, a highly chemical recipe can be used to achieve high mask selectivity. Such a recipe can include, for example the following characteristics: the amount of O₂ can be 30 sccm (standard cubic centimeters per minute), the pressure can be 85 mTorr, the ICP forward power can be 60 W, the RF generator power can be 150 w, and the temperature can be 10° C. Operation at 85 mTorr can reduce ion bombardment by reducing the ion mean free path and can correspond to isotropic chemical etching. Alternatively, a highly kinetic ICP etching process can be applied. Such a recipe can include, for example, the following characteristics: the amount of O₂ can be 70 sccm, the amount of Ar can be 10 sccm, the pressure can be 15 mTorr, the ICP forward power can be 500 W, the RF generator power can be 450 W, and the temperature can be 10° C. In yet other embodiments, different etching processes, suitable to vertically etch the diamond substrate, can be applied. As an example, an ICP can be used with the following process parameters: oxygen content of 40 sccm, chamber pressure of 20 mTorr, 300 W RF power and 350 W ICP power.

With reference to FIG. 3, vertical etching using ICP can include the use of an etching device 320. Time varying electric current can be passed through one or more coils 327 to create a time-varying magnetic field, which can induce electric currents in a gas 323, such as argon, to form plasma 325. The plasma ions 325 can be directed to the diamond substrate 110 and can etch the exposed portion 112 to create the nanoposts 121.

After etching (102), the hard mask can be removed, resulting in a plurality of nano-posts 121 corresponding to the masked regions 111 of the diamond substrate 110. That is, if the masked regions 111 each have a diameter of approximately 50 nm, the resulting nanoposts 121 can likewise have a diameter of approximately 50 nm. In like manner, the predetermined etch depth, which can be controlled via ICP recipe and operational parameters, can correspond to the height of the nanoposts. One of ordinary skill in the art will appreciate that, while the nanoposts 121 depicted in FIG. 1 are shown as cylindrical for purpose of illustration, and not limitation, the nanoposts 121, and likewise the harvested nanostructures 131 need not have a cylindrical shape. For example, as depicted in FIG. 2c, the diameter of the nanoposts 121 can increase from the top of the nanoposts to the base connecting to the diamond substrate (e.g., resulting from the etching process). Likewise, as depicted in FIG. 2d, the resulting nanostructures can have an irregular shape.

The nanoposts 121 can be harvested (103) to obtain one or more nanostructures 131 with a diameter corresponding to the predetermined diameter and a length corresponding to the predetermined depth. As embodied herein, harvesting the nanoposts 121 can include removing the nanoposts 121 from the diamond substrate 110 by mechanical shaving. For example, with reference to FIG. 3, a second diamond slab 350 can be dragged at an angle across the substrate to cleave the nanoposts 121 from the diamond substrate at their bases. A surface of the diamond slab 350 can be positioned in parallel with a plane of the diamond substrate 110 at the predetermined etch depth such that an acute angle of the diamond slab 350, when dragged, can exert a force at the base of the nanoposts 121 and thus cleave them from the underlying diamond substrate 110. Additionally or alternatively, harvesting can include sonication. For example, the diamond substrate 110 can be placed in a vessel containing a solvent (e.g., IPA) and put into a sonication bath and agitated to remove the nanoposts and thus create nanostructures 131. Alternatively, a sonication horn can be placed into the vessel to agitate the solvent.

For purpose of example, and not limitation, harvesting (103) of the diamond nanostructures 131 can include transferring the diamond nanostructures 131 using a PDMS stamping technique. The PDMS can be made sticky so as to pick up the diamond nanostructures and transfer them to a different substrate (e.g., substrate 140). In other embodiments, alternative transfer techniques can be used. For example, a bisbenzocyclobutene (BCB) layer can be used as the adhesive for permanent lamination.

In accordance with an exemplary embodiment, atomic defects, including color centers, can be created in the diamond nanostructures. For example, nitrogen atoms 141 can be implanted (104) into one or more of the diamond nanostructures 131 fabricated as disclosed herein. For purpose of illustration, and not limitation, N15 atoms 141 can be can be implanted in coordination with regular implantation runs, using particle size-dependent implantation dosages and energies from established recipes. For purpose of illustration, and not limitation, atoms can be implanted at a predetermined depth by controlling the ion implantation energy. The atom implantation energy required to implant atom at a predetermined depth can be computed with the use of known models. For example, the Stopping and Range of Ions in Matter simulation package, provided by J. F. Zeigler and available at www.srim.org, allows for such a calculation. In general, required atom implantation energy is positively correlated with ion implantation depth. For example, 6 keV implantation energy can result in implantation depth of several nm.

Implantation of atomic defects and/or color centers can be accomplished using an ion implantation device. The ion implantation device can include, for example, an accelerator configured to emit particles with predetermined energies in a beamline. Commercially available ion implantation devices include, for purpose of example and not limitation, the 4 Megavolt Dynamitron ion implanter (Radiation Dynamics, Inc.) and the 400 Kilovolt Varian 400-10A Implanter (Exitron). For purpose of illustration, and not limitation, the Dynamitron ion implanter can emit particles with energies up to approximately 4 MeV. The Varian Implanter can emit particles with energies ranging from approximately 50 to 400 keV.

If desired, nitrogen atoms can be implanted to form NV color centers in the diamond nanostructure. The implanted nitrogen atoms can be converted to negatively charged nitrogen vacancy centers by performing one or more annealing schedules. For example, the diamond nanostructure can be annealed at approximately 850° C. to mobilize vacancies in the diamond nanostructure crystal and thereby form nitrogen vacancy centers. Such annealing can include, for example, vacuum (˜1 Torr) annealing using a split tube furnace with vacuum flanges and a vacuum pump. The surface of the diamond nanostructure can then be oxidized at approximately 475° C. to change the surface termination of the diamond surface and stabilize at least some of the negatively charged nitrogen vacancy centers. For example, oxidization can be performed using a hot plate or split tube furnace.

As embodied herein, implantation of ions into the resulting nanostructures can be performed if desired. Additionally or alternatively, implantation of ions can be performed prior to fabricating the diamond nanostructures. For example, nitrogen atoms can be implanted and converted into NV centers, as described herein, into the diamond substrate prior to application of the hard mask, etching, and harvesting. In this manner, the nanostructures resulting from masking, etching, and harvesting can include the pre-implanted NV centers. While described herein with reference to NV centers, the disclosed subject matter is not intended to be limited to the creation of NV centers. Rather, any type of atomic defect or color center can be created in the diamond nanostructures, as desired. Moreover, the diamond substrate used for fabrication of the diamond nanostructures can include preexisting color centers or atomic defects. For example, certain diamond substrates can be fabricated using techniques that result in the presence of NV centers or other atomic defects, and natural diamond substrates having preexisting NV centers or other atomic defects can be used. The existence of preexisting atomic defects centers can obviate the need for ion implantation. It is recognized, however, that additional color centers and/or other atomic defects can be created by ion implantation, as desired.

For purpose of illustration, and not limitation, nanostructures of different sizes produced in accordance with the techniques disclosed herein can be tested for uniformity and yield of the fabrication process, and nanostructures for optimal magnetic field sensitivity and subsequent processes can be identified according to techniques known to those of ordinary skill in the art. For example, the resulting structures can be characterized via optical (OM), scanning electron (SEM) and μRaman confocal microscopies. In addition, atomic force (AFM) and tunneling microscopes (TEM) can be used to evaluate the nanostructures after removal from the parent crystals.

In an exemplary embodiment, the diamond substrate can be re-used after harvesting of the nanostructures from its surface. For example, after harvesting, another hard mask can be applied and a further set of nanostructures can be fabricated. For purpose of illustration, and not limitation, the surface of the diamond substrate can be conditioned, such by one or more annealing procedures to graphitize and remove a surface layer of the diamond substrate, prior to application of the mask. Additionally or alternatively, the surface can be mechanically polished, boiled in a corrosive mixture of acids, and/or otherwise conditioned to ensure a suitable surface.

The techniques disclosed herein can provide for diamond nanostructures suitable for use in a variety of applications, including for example, applications in the life sciences (including biology, medicine, and the like), chemistry, physics, material science and engineering, telecommunications, and quantum information processing.

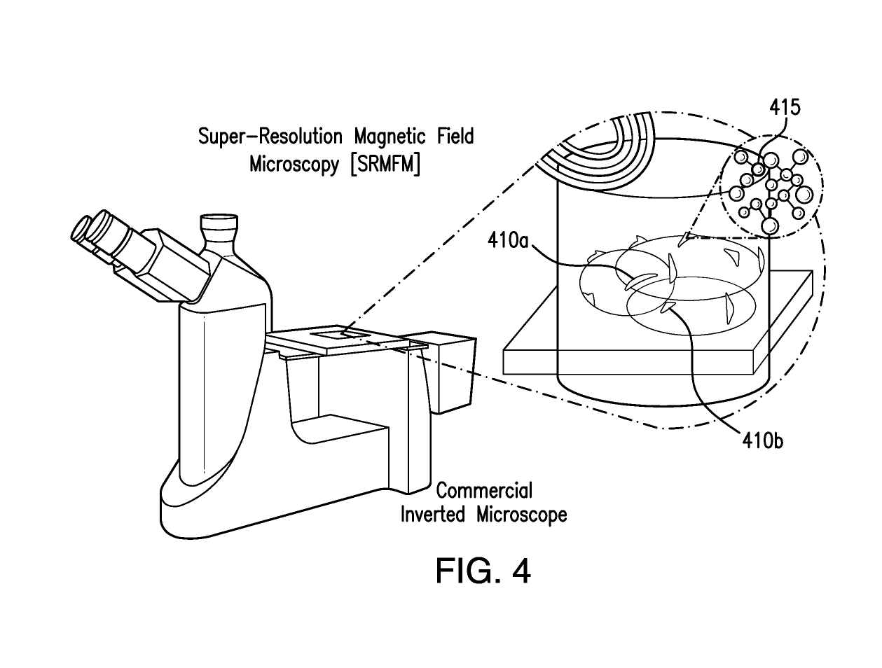

For purpose of illustration, and not limitation, one exemplary application in which the diamond nanostructures fabricated in accordance with the disclosed subject matter can be used is super-resolution magnetic field microscopy. As illustrated in FIG. 4, the diamond nanostructures (e.g., 410a and 410b [collectively 410]) fabricated according to the techniques disclosed herein can be added to, for example, a biological sample. The NVs (e.g., NV 415) present in the diamond nanostructures 410 can be used to image magnetic fields with high sensitivity using dynamic decoupling spin protocols. The magnetic field sensitivity achieved with the diamond nanostructures described herein can provide for, e.g., the determination of the elemental composition of small ensembles of spins (e.g., in chemical analysis of single molecules/bio-detection), and thus enable magnetic resonance imaging with nm-scale resolution. Additionally, among numerous other applications, the nanostructures described herein can be employed to image neural activity via imaging of magnetic fields due to radial and axial currents.

For purpose of illustration and not limitation, the NV center can consist of a nitrogen atom adjacent to a vacancy in the diamond lattice. In the negatively charged state, the NV center's electron spin can be coherently manipulated by addressing the transition between the mₛ=0 and mₛ=±1 sublevels of its ground state triplet, and it can be read-out optically through a spin-dependent intersystem crossing. A figure of merit in quantifying the quality of a given NV spin system can be the electron phase coherence time T₂, which can be a phenomenological decay constant that can characterize how long the phase of the system coherently evolves. The spin coherence time of NV centers in bulk and nanocrystalline type Ib diamond can be limited in part by the stochastic fluctuations of the magnetic field induced by the bath of paramagnetic impurities and surface defects with times T₂*˜250 ns and T₂˜3 μs at 100 ppm. The growth of CVD diamond can be controlled to limit nitrogen inclusion and reduce the number of paramagnetic carbon-13 nuclear spins. The purity of such material can increase the NV coherence time beyond milliseconds with concomitant improvements in sensing applications. For purpose of illustration and not limitation, certain diamond nanocrystals attained via bottom-up CVD growth can have coherence lifetimes of 10 μs or less.

For purpose of illustration and not limitation, diamond nanocrystals can be fabricated directly from high-purity bulk CVD diamond with less than 5 ppb native nitrogen and natural ¹³C density (e.g., CVD diamond commercially available from Element Six). The fabrication procedure can be scalable across large diamond surfaces and can employ deposited metal as a porous etch mask for reactive ion etching with oxygen gas in an inductively coupled plasma (ICP). Certain techniques for scalable creation of diamond nanowires can involve a thermal annealing step to create metallic nanoparticle masks for a subsequent Ar/He or oxygen dry etch. Such techniques can allow the fabrication of closely packed pillars on the scale of tens of nanometers across an entire sample surface, which can be difficult and time-consuming using traditional electron beam lithographic or focused ion beam techniques. An exemplary technique can also include an oxygen ICP etch that can preserve the spin properties of nearby NV centers.

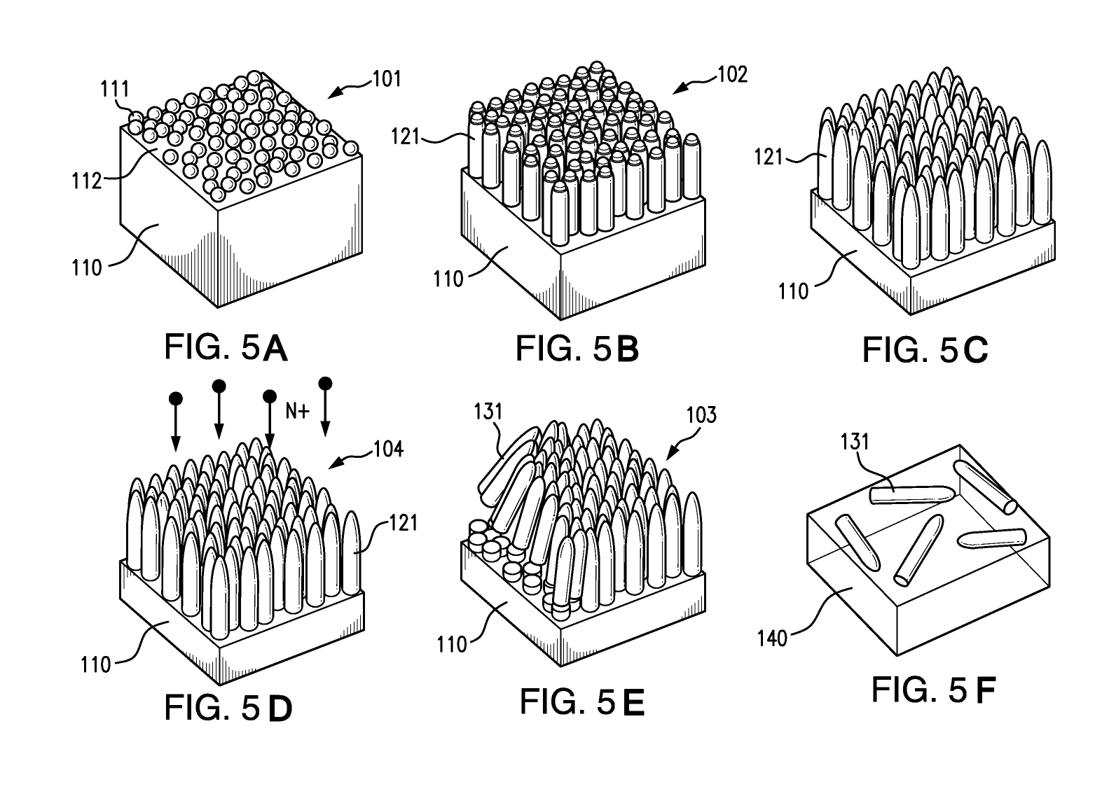

FIG. 5A-5F is a schematic flow chart illustrating techniques for fabrication of diamond nanostructures in accordance with an exemplary embodiment of the disclosed subject matter. Techniques for fabricating diamond nanostructures 131 can include applying (101) a self-assembled hard mask to a surface of a diamond substrate 110 to define a pattern of masked region 111 having a predetermined diameter surrounded by an exposed portion 112, as discussed herein. For example, applying the self-assembled hard mask can include depositing gold/palladium (AuPd) grains on a surface of diamond substrate 110. The exposed portion 112 of the diamond substrate 110 can be vertically etched (102) to a predetermined depth using ICP to form a plurality of nanoposts 121 corresponding to the masked regions 111, as discussed herein. After etching (102), the hard mask can be removed (102a), resulting in a plurality of nano-posts 121 corresponding to the masked regions 111 of the diamond substrate 110, as discussed herein. That is, if the masked regions 111 each have a diameter of approximately 50 nm, the resulting nanoposts 121 can likewise have a diameter of approximately 50 nm. Nitrogen atoms 141 can be implanted (104) into one or more of the diamond nanoposts 121, as discussed herein. The nanoposts 121 can then be harvested (103) to obtain one or more nanostructures 131 with a diameter corresponding to the predetermined diameter and a length corresponding to the predetermined depth, as discussed herein. For purpose of example, and not limitation, harvesting (103) of the diamond nanostructures 131 can include transferring the diamond nanostructures 131 using a PDMS stamping technique. The PDMS can be made sticky so as to pick up the diamond nanostructures and transfer them to a different substrate (e.g., substrate 140).

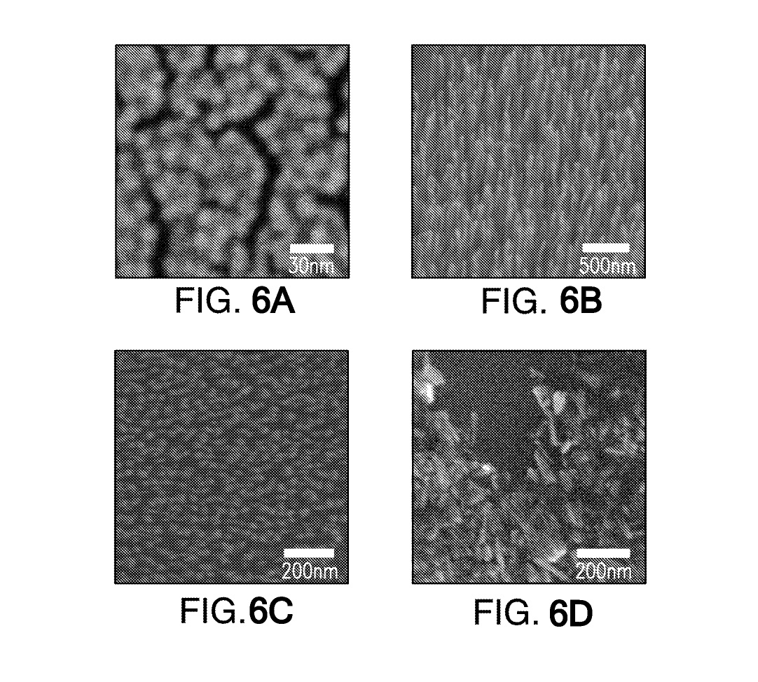

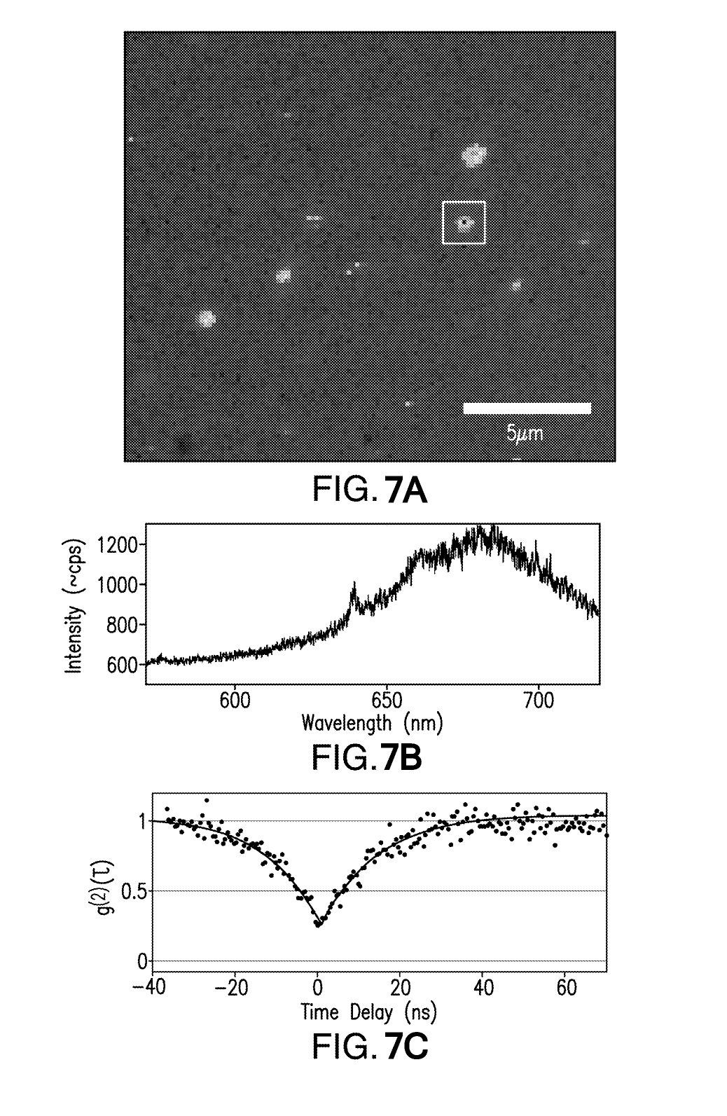

FIG. 6A-6D shows a scanning electron micrographs of (a) an AuPd mask 111, (b) side view and (c) top-view of nanoposts 121 attached to bulk diamond, and (d) nanostructures 131 separated from bulk and transferred onto a silicon substrate, in accordance with an exemplary embodiment of the disclosed subject matter. FIG. 7A-7C shows (a) a scanning confocal image of CVD nanodiamonds on glass with the fluorescence from a single NV indicated by the red square, (b) a spectrum of a single NV center in a CVD diamond nanocrystal showing the NV ZPL at 638 nm, and (c) the second-order autocorrelation function of NV photoluminescence indicating single-emitter behavior with g⁽²⁾(0) less than 0.5 and a curve fit to function 1+Ae^{-|(t/τ)|}(0)=0.247 and τ the excited state lifetime 13.57 ns, in accordance with an exemplary embodiment of the disclosed subject matter.

For purpose of illustration and not limitation, deposited AuPd grains can serve as an etch mask 111 that allows the formation of densely patterned nanoposts 121 while the mask is destroyed during the etching. Subsequent SEM imaging shown in FIGS. 6B and 6C can show a high density of elongated nanostructures with diameter 50±15 nm and height of 150±75 nm extending throughout the diamond surface. CVD nanocrystals can be produced at a number density of ˜10¹⁰ cm⁻² simultaneously across the sample area, allowing for scaling to wafer-size substrates. The bulk diamond can be reprocessed after the removal of a layer of nanocrystals, allowing for the creation of large quantities of nanodiamond economically from high-purity bulk material which can be hundreds of micrometers in thickness.

For purpose of illustration and not limitation, after etching the diamond nanoposts 121 (FIGS. 6B and 6C) can be implanted with nitrogen and processed to form NV centers in the CVD nanodiamonds before mechanically separating them from the bulk substrate (FIG. 6D). The nanodiamonds can be characterized at room temperature, for example, using confocal fluorescence microscopy with an oil immersion objective (NA=1.3) and excitation by a 532 nm continuous wave laser. FIG. 7A shows a confocal scan of nanodiamonds transferred onto glass. The fluorescence spectrum (FIG. 7B) can match that of the negatively charged NV with a zero phonon line (ZPL) near 638 nm. Photon antibunching from such sites can demonstrate the presence of single NVs (FIG. 7C).

For purpose of illustration and not limitation, AuPd grains can be sputtered (101) onto diamond resulting in surface coating the masked region 111 of distinct AuPd grains as shown in FIG. 6A. The pattern can be transferred onto diamond via oxygen plasma etching (102) in an Oxford ICP 80 tool at a pressure of 15 mTorr with 200 W DC and 500 W ICP power and flow rates of 90 sccm O₂ ad 30 sccm Ar. After etching (102), the diamond surface can be implanted (104) with N at a dose of 2×10 N cm⁻² and an energy of 50 keV for an estimated implant depth of 73±16 nm as calculated SRIM. At this dose, NV conversion efficiency can be expected to be 1%, as observed in similar samples, and 40% of the CVD nanodiamonds can be expected to contain NVs. The diamond can be annealed at 850° C., for example, for about 2 hours to mobilize vacancies, and the diamond can be cleaned, for example, in a boiling nitric, sulfuric, and perchloric acid solution to achieve oxygen surface termination. The structures can be mechanically separated (103) from the bulk diamond using a diamond tip. Each removal pass can remove a surface area of, for example, about 1000 μs² from the diamond surface. The dislocated nanodiamonds 131 can be transferred directly onto a substrate 140, for example, one or more glass coverslips by contact and driving with an external piezoelectric driver with a process efficiency of ˜1%.

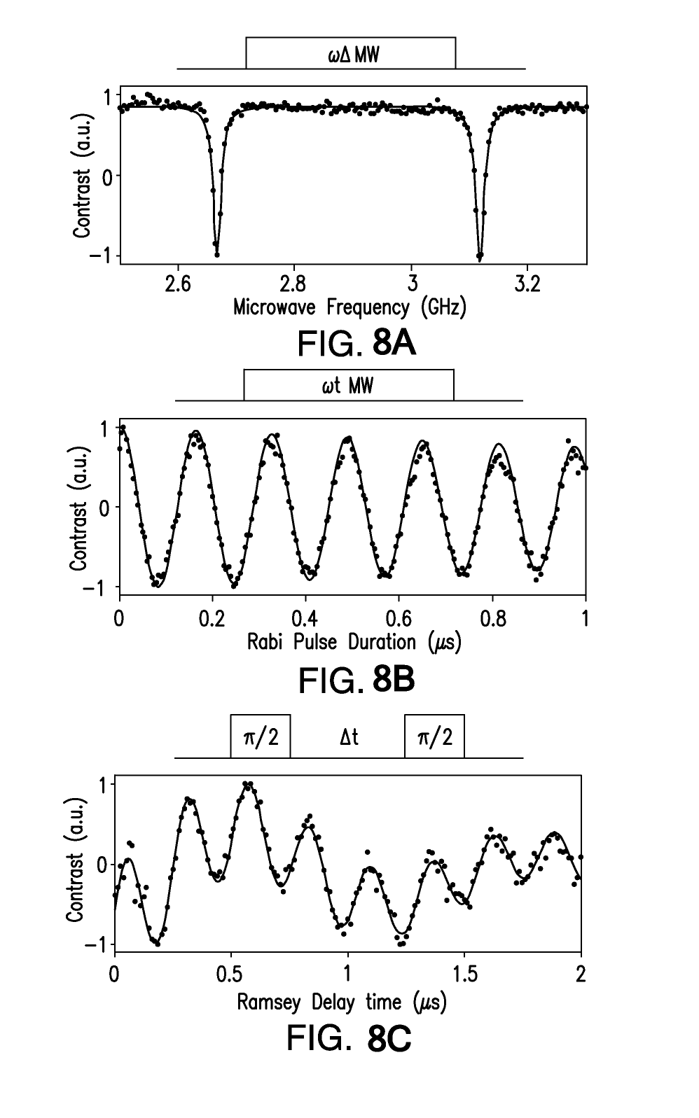

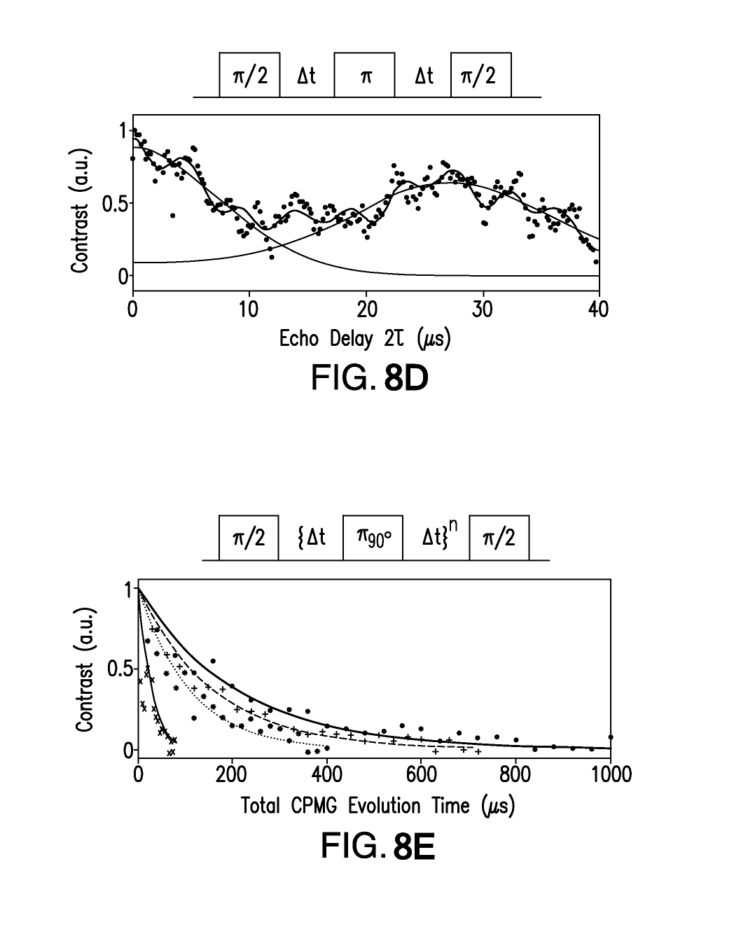

FIG. 8A-8E shows the spin characterization for two exemplary NV centers, in accordance with an exemplary embodiment of the disclosed subject matter. Contrast can be normalized to the overall fluorescence with 1 corresponding to the mₛ=0 bright state and −1 corresponding to the mₛ=1 dark state. The overall contrast can be ˜15% at a total fluorescence rate of 60 kcps. Referring to exemplary NV A, FIG. 8A shows a continuous-wave ESR under static magnetic field. FIG. 8B shows Rabi oscillations with a line fit to function Ae^{-t/T}_{2,rabi} sin(bt+c)+d, T₂,rabi=3.53 μs. FIG. 8C shows Ramsey interferometry with a line fit to function Ae^{-t/T}₂*Σₖ sin(bₖt+cₖ)+d, T₂*=1.83 μs. FIG. 8D shows Hahn Echo with lines 801 depicting Gaussian fits over range of revival peak and a line 802 fit to Ae^{-t/T}₂Σᵢ(e^{((t-T}ᵢ^{)/(δT))̂2})Σᵢ(sin(bⱼt+cⱼ))+d, decay constant T₂=79 μs. Referring to exemplary NV B, FIG. 8E shows CPMG-n for n=1 (811), n=20 (812), 30 (813), and 40 (814). The lines are exponential fits with T₂=210 μs for n=40.

Spin measurements can be performed on single NV centers with a small static magnetic field of approximately 70 G along the NV axis to lift the degeneracy of the mₛ=±1 magnetic ground-state sublevels. FIG. 8A shows the electron spin resonance under continuous wave excitation with power-broadened line width Δ [symbol] =16 MHz>>1/T₂*. FIG. 8B shows representative Rabi oscillations, obtained using the pulse sequence shown in the inset. The oscillations can show a decay time T_{2,Rabi}=2.53 10 μs that can exceed observed times in HPHT nanodiamonds by an order of magnitude.

The coherence times of the system can be characterized through Ramsey, Hahn Echo, and Carr-Purcell-Meiboom-Gill (CPMG) sequences. FIG. 8C shows Ramsey measurements, using the sequence in the inset. The measured T₂* value of 1.83 μs can be determined from a fit of exponentially decaying sine functions. To further increase the coherence time, a Hahn echo measurement can be performed that can decouple the NV from quasi-static magnetic fields (FIG. 8D). FIG. 8D can show are two Gaussian peaks, which can be attributed to the effect of local ¹³C nuclear spins, periodic modulation attributed to the effects of other strongly coupled local nuclear spins, including nitrogen, and an overall exponentially decaying coherence envelope. A relatively long T₂ time of 79 μs can be measured. This T₂ can represent a significant increase over T₂* and can demonstrate that the coherence of this NV can be limited at least in part by nuclear spin interaction rather than local electronic defects, which can contrast HPHT nanodiamonds. CPMG sequences can be employed to further decouple the NV spin and extend coherence through repeated spin-refocusing pulses. These measurements, taken with CPMG repetition up to n=40 on a second CVD nanodiamond NV B (FIG. 8E), can result in an exceptionally long observed coherence time T₂=210 μs, which can represent and increase by a factor of 7 from the n=1 case. These measurements can show no ¹³C modulation due to a lower sampling frequency, which can expose the overall coherence envelope.

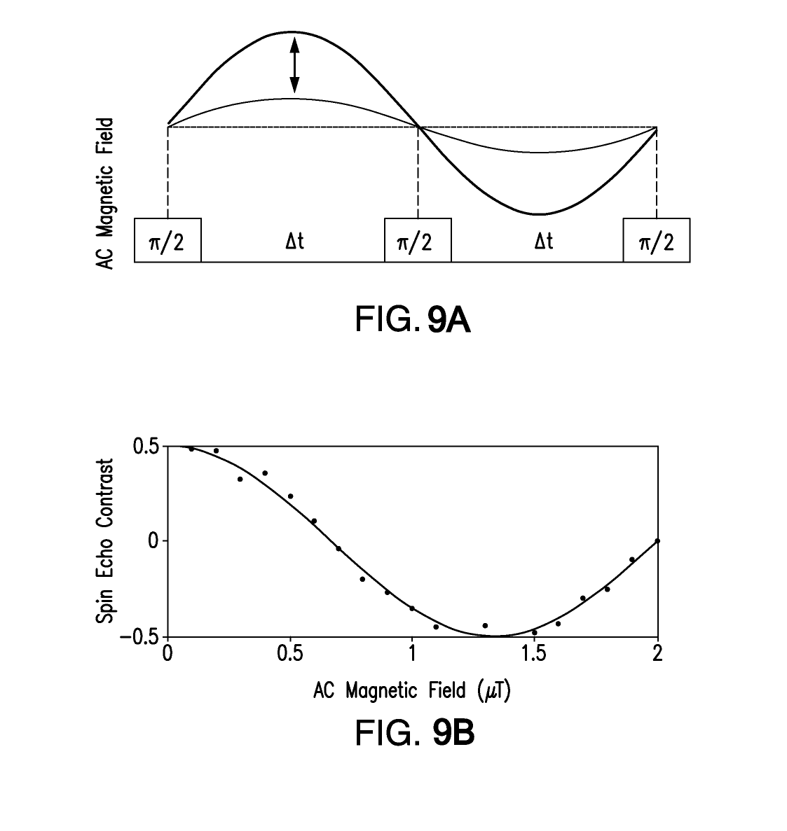

This relatively long spin coherence times in the high-purity CVD diamond nanocrystals discussed herein can enable high-precision alternating current (AC) magnetometry. FIG. 9A-9B shows (a) a magnetic field and pulse sequence for an AC magnetic field with a frequency of 1/2ΔT=35.7 kHz while its amplitude is varied and (b) magnetometry results for an AC magnetometry sequence performed on an exemplary NV center, consisting of 106 sequence repetitions per point, with a total measurement time per sequence of 32 μs. The measured sensitivity is 290 nT Hz^{-1/2}. By Matching the frequency of an alternating magnetic field to the repetition rate of the Hahn echo sequence (FIG. 9A), the NV spin can acquire a phase proportional to the magnetic field strength that in turn can be read-out optically through the NV spin-dependent fluorescence. The minimum detectable field strength ^{δ}B can be given by the ratio of the uncertainty in the signal ^{σ}s to the change in signal per unit magnetic field (^{δ}S/^{δ}B) and can scale with the square root of the coherence time (Tₛ)^{-1/2}. FIG. 9B shows a measurement of the CVD nanodiamond output fluorescence as a function of external magnetic field amplitude, using a Hahn echo sequence with total sensing time τ=32 μs. Because of the long coherence time of the CVD nanocrystals and resulting high slope (δS/δB), a record magnetic field sensitivity of δB=290 nT Hz^{-1/2} can be achieved for an NV center in nanodiamond.

The coherence times achieved for NV centers in the CVD nanodiamonds can be very high, as discussed herein, and the nanodiamonds fabricated in large quantities, as discussed herein. The repeatability and yield of the fabrication process can also be considered. In some embodiments, not every NV center in the nanodiamonds can exhibit long coherence times. For example, in some experiments, approximately 10% of bright spots with clear ESR signature can show coherence times in excess of 10 μs. This number can be as high as 40% in similarly prepared bulk diamond, which can be irradiated with a dose of 10⁸ ions cm⁻² and energies from 30 to 300 keV. The lower coherence time in the nanocrystals can be attributed at least in part to the increase in N density of over 4 orders of magnitude to 2×10 N cm⁻², which, can be used in the fabrication process discussed herein to realize a high expected NV per nanocrystal yield of ˜40%. Large N implantation density can be used for a reasonable NV yield within, for example, a 50 nm diameter of the CVD nanocrystals, and the local paramagnetic spin bath density can be higher than that in systems that do not require as high NV density, such as bulk CVD diamond. In addition, low-energy implantation can localize paramagnetic N defects in a thin layer rather than distributing them throughout the diamond, which can result in a high local defect density. As the dose is decreased, T₂ can increases due to the longer average spacing between a given NV center and the spin bath, but the corresponding NV number can decrease. To increase NV density with long phase coherence time, N to NV creation yield can be improved from the nominal 1% to create NVs with fewer implanted nitrogen atoms. For purpose of illustration and not limitation, such an improvement can be achieved by co-implantation with other species to create additional vacancies. Additionally or alternatively, isotopic purification, high-temperature (>1200° C.) annealing, and diamond regrowth can be utilized. These techniques can alleviate observed flaws with shallow-implanted NV centers that can be observed even in bulk diamond, such as charge instability and limited coherence times that can be attributed to other crystal defects. Advanced spin control protocols, such as extended CPMG sequences, can also be used to increase the coherence time of this system. The magnetic field sensitivity can likewise increase through the use of multipulse magnetometry sequences, which can increase the sensing time to the full T₂ time of 210 μs observed in the CPMG measurements and thus can reach a predicted sensitivity of 105 nT Hz^{-1/2}. Even without these sequences, however, NVs in the fabricated CVD nanodiamonds discussed herein can demonstrate the highest phase coherence time of any solid-state qubit in a nanoparticle.

The fabrication and characterization of high-purity CVD diamond nanocrystals with average diameter of 50 nm (e.g. 50±15 nm) can demonstrate long coherence times of the NVs they contain, which can exceed 200 μs. Through the use of high-quality starting material and CPMG decoupling, a phase coherence time can exceed that of certain HPHT nanodiamond by 2 orders of magnitude. With spin properties similar to those found in bulk diamond, NVs contained in the high-quality nanocrystals described herein can allow protocols that have only been implemented in bulk systems, such as spin-based electric field sensing, at the nanoscale. Furthermore, diamond nanocrystals can be well suited for use as biological probes, and the increased field sensitivity demonstrated herein can enables measurement of relevant systems, such as neural networks, with distributed and highly localizable sensors. Because of their small volume, the fabricated CVD nanocrystals can be used for integration with photonic structures in silicon or III-V materials, where the NV could act as a spin qubit without significantly perturbing the cavity or waveguide mode. The fabrication technique described herein can lead to a nanodiamond diameter of less than 20 nm, dependent on the metal nanoparticle sizing, and the use of isotopically purified host material, enhanced dose parameters, and advanced control sequences can extend coherence times to the millisecond level as observed in bulk diamond.

The combination of long spin coherence time and nanoscale size can make NV centers in nanodiamonds interesting for quantum information and sensing applications. For purpose of illustration and not limitation the NV center in nanodiamond has been investigated across a broad range of applications, including its use as a spin qubit in a hybrid photonic architecture and as a highly localized sensor of temperature and magnetic fields that can be integrated with biological systems. The performance of the NV for such applications can depend at least in part on its electron spin phase coherence time. However, certain high-pressure high-temperature (HPHT) nanodiamonds can have a high concentration of paramagnetic impurities that can limit their spin coherence time to the order of microseconds, less than 1% of that observed in bulk diamond. A porous metal mask and a reactive ion etching process can be used to fabricate nanocrystals from high-purity CVD diamond. NV centers in these CVD nanodiamonds can exhibit record-long spin coherence times in excess of 200 μs, which can enable magnetic field sensitivities of up to 290 nT Hz^{-1/2} or more with the spatial resolution characteristic of a nanoscale probe, for example, a 50±15 nm diameter probe.

For purpose of illustration and not limitation, a porous metal mask and a self-guiding reactive ion etching process can enable rapid nanocrystal creation across the entirety of a high-quality CVD diamond substrate. High-purity CVD nanocrystals can be produced in this manner and can exhibit single NV phase coherence times reaching up to 210 μs or longer and magnetic field sensitivities of up to 290 nT Hz^{-1/2} or more without compromising the spatial resolution of a nanoscale probe.

The presently disclosed subject matter is not to be limited in scope by the specific embodiments herein. Indeed, various modifications of the disclosed subject matter in addition to those described herein will become apparent to those skilled in the art from the foregoing description and the accompanying figures. Such modifications are intended to fall within the scope of the appended claims.

1. A method for fabricating diamond nanostructures, comprising:
applying a hard mask to a surface of a diamond substrate to define thereon a pattern of masked regions having a predetermined diameter surrounded by at least one exposed portion;
vertically etching the exposed portion of the diamond structure to at least the predetermined depth to thereby form a plurality of nanoposts corresponding to the masked regions; and
harvesting at least one nanopost from the diamond substrate, thereby obtaining a nanostructure having a diameter corresponding to the predetermined diameter, and a length corresponding to the predetermined depth.

2. The method of claim 1, wherein the diamond substrate includes a diamond substrate selected from the group consisting of high-purity diamond, low purity diamond, single crystal diamond, or multi-crystal diamond.

3. The method of claim 1, wherein applying the hard mask includes applying a high-density monolayer of self-assembled dielectric or metallic nanoparticles.

4. The method of claim 1, wherein applying the hard mask includes heating a thin, evaporated layer of gold on the surface of the diamond substrate to thereby form a plurality of gold droplets, wherein the plurality of gold droplets correspond to the masked regions.

5. The method of claim 1, wherein applying the hard mask includes damaging the surface of the diamond substrate to create variations in height of the surface, and wherein the masked regions correspond to the variations in height.

6. The method of claim 1, wherein vertically etching the exposed portion includes using inductively coupled plasma or reactive ion etching.

7. The method of claim 1, wherein the predetermined diameter of the masked regions is between approximately 25 nm and 225 nm, and wherein the predetermined depth is between approximately 50 nm and 1 mm.

8. The method of claim 1, wherein the predetermined diameter of the masked regions is approximately 50 nm and the predetermined depth is approximately 80 nm.

9. The method of claim 1, wherein the predetermined diameter of the masked regions is approximately 200 nm and the predetermined depth is approximately 400 nm.

10. The method of claim 1, wherein harvesting the at least one nanopost includes one or more of mechanical shaving or applying sound energy to remove the nanoposts from the diamond substrate.

11. The method of claim 1, further comprising repeating applying the hard mask, vertically etching the exposed portion of the diamond substrate, and harvesting the at least one nanopost to thereby perform layer by layer fabrication of diamond nanostructures from the diamond substrate.

12. The method of claim 1, further comprising:
implanting nitrogen atoms into the diamond nanostructure;
annealing the diamond nanostructure at approximately 850° C. to mobilize vacancies in the diamond nanostructure crystal and thereby form nitrogen vacancy centers; and
oxygenating the surface of the diamond nanostructure by oxidation at approximately 475° C. to change the surface termination of the diamond surface and stabilize at least some of the negatively charged nitrogen vacancy centers.

13. A system for fabricating diamond nanostructures using a diamond substrate, comprising:
a masking device, adapted for operational coupling to the diamond substrate, and for applying a hard mask to a surface of the diamond substrate to define thereon a pattern of masked regions having a predetermined diameter surrounded by at least one exposed portion;
an etching device, adapted for operational coupling to the diamond substrate, and for vertically etching the exposed portion to at least the predetermined depth to thereby form a plurality of nanoposts corresponding to the masked regions; and
a harvesting device, adapted for operational coupling to the diamond structure, and for harvesting at least one nanopost from the diamond substrate to obtain a nanostructure having a diameter corresponding to the predetermined diameter, and a length corresponding to the predetermined depth.

14. The system of claim 13, wherein the diamond substrate includes a diamond substrate selected from the group consisting of high-purity diamond, low purity diamond, single crystal diamond, or multi-crystal diamond.

15. The system of claim 13, wherein the masking device includes one or more of a spin coater, a dip coater, and sputtering equipment adapted to apply a high-density monolayer of self-assembled dielectric or metallic nanoparticles.

16. The system of claim 13, wherein the masking device includes one or more of a thermal evaporator, an e-beam evaporator, and sputtering equipment adapted to apply the hard mask by heating a thin, evaporated layer of gold on the surface of the diamond substrate to thereby form a plurality of gold droplets, wherein the plurality of gold droplets correspond to the masked regions.

17. The system of claim 13, wherein the masking device includes one or more of a sputtering device and an e-beam evaporator adapted to damaging the surface of the diamond substrate to create variations in height of the surface, and wherein the masked regions correspond to the variations in height.

18. The system of claim 13, wherein the etching device includes one or more of an inductively coupled plasma device or a reactive ion etching device.

19. The system of claim 13, wherein the predetermined diameter of the masked regions is between approximately 25 nm and 225 nm, and wherein the predetermined depth is between approximately 50 nm and 1 mm.

20. The system of claim 13, wherein the predetermined diameter of the masked regions is approximately 50 urn and the predetermined depth is approximately 80 nm.

21. The system of claim 13, wherein the predetermined diameter of the masked regions is approximately 200 nm and the predetermined depth is approximately 400 nm.

22. The system of claim 13, wherein the harvesting device includes a mechanical device adapted to drag a second diamond slab having a surface arranged parallel to a plane of the diamond substrate across the plane at the predetermined depth to cleave the nanoposts from the diamond substrate.

23. The system of claim 13, wherein the harvesting device includes one or more of a vessel containing a solvent adapted to receive the diamond substrate, an agitator adapted to agitate the solvent, and a sonication horn adapted to agitate the solvent for removing the nanopost from the diamond substrate and thereby obtain the nanostructure.

24. The system of claim 13, wherein the masking device, the etching device, and the harvesting device are further adapted for repeating application of the hard mask, vertical etching of the exposed portion of the diamond substrate, and harvesting of the at least one nanopost to thereby perform layer by layer fabrication of diamond nanostructures from the diamond substrate.

25. The system of claim 13, further comprising:
an ion implantation device, adapted for operational coupling to the diamond substrate, and for implanting nitrogen atoms into the diamond nanostructure;
an annealing device, adapted to receive and anneal the nanostructure at approximately 850° C. to mobilize vacancies therein and thereby form nitrogen vacancy centers; and
an oxidation device, adapted to receive and oxiginate the surface of the annealed nanostructure by oxidation at approximately 475° C. to change the surface termination of the diamond surface and stabilize at least some of the negatively charged nitrogen vacancy centers.
